(19) United States
(12) Patent Application Publication
(10) Pub. No.: US 2011/0303528 A1
(43) Pub. Date: Dec. 15, 2011

(54) METHOD AND APPARATUS FOR SPUTTERING FILM CONTAINING HIGH VAPOR PRESSURE MATERIAL

(75) Inventor: Kun-Ping Huang, Miaoli County (TW)

(73) Assignee: INDUSTRIAL TECHNOLOGY RESEARCH INSTITUTE, Hsinchu (TW)

(21) Appl. No.: 12/853,307

(22) Filed: Aug. 10, 2010

(30) Foreign Application Priority Data
Jun. 11, 2010 (TW) 99119097

(51) Int. Cl. C23C 14/34

(52) U.S. Cl. 204/192.15; 204/298.12; 204/298.13

(57) ABSTRACT

A method and an apparatus for sputtering a film containing high vapor pressure material are provided. The apparatus includes a chamber, a sputtering gun installed in the chamber, a complex target disposed on the sputtering gun, and a substrate holder. The complex target includes a main target and a plurality of pellets, and a material of the pellets is at least one high vapor pressure material that is a material with a vapor pressure greater than 1×10⁻⁹ ton at 1000° C. The substrate holder is installed in the chamber opposite to the complex target.

### CROSS-REFERENCE TO RELATED APPLICATION

This application claims the priority benefit of Taiwan application serial no. 99119097, filed on Jun. 11, 2010. The entirety of the above-mentioned patent application is hereby incorporated by reference herein and made a part of this specification.

### BACKGROUND

1. Technical Field

The disclosure relates to an apparatus and a method of sputtering a film containing a high vapor pressure material.

2. Description of Related Art

Vacuum sputtering has become the most adopted sputtering process of current large solar panels due to its characteristics of producing products with high quality and large area. However, the components of high vapor pressure are easily evaporated during sputtering process and the subsequent annealing process, such that the film has abnormal composition ratio, thereby affecting product quality.

In U.S. Pat. No. 7,632,701 B2, a solution is proposed, where a chemical method is utilized to perform additional selenization and sulfurization. Nevertheless, extra steps create more risks. The large area copper indium gallium diselenide (CIGS) solar cell introduced by Honda Soltec is used as an example. The CIGS solar cell performs selenization with H₂Se gas. However, H₂Se gas is poisonous, flammable, and explosive, and is thus unfavorable to be used in mass production due to possible hazards.

Moreover, when the sputtering target contains high vapor pressure components, the components are easily lost in the sputtering process due to the temperature. In that case, the composition ratio of the film is imprecise, which results in pore defect in the crystalline structure of the film, and consequently the film material has poor property resulting in the deterioration of product quality. Take the semiconductor copper process as an example, in U.S. Patent Publication No. 20090166181 A1, a chemical method mixing a low vapor pressure material with high vapor pressure components is provided to prevent the loss of high vapor pressure components. However, the copper film obtained from the patent has impurities which lower the quality of the film.

### SUMMARY

An apparatus of sputtering a film containing a high vapor pressure material is introduced herein. The apparatus is capable of manufacturing films having no impurity phase and containing a high vapor pressure material with an accurate composition ratio.

A method of sputtering a film containing a high vapor pressure material is further introduced herein. The method omits an additional filling process (i.e. a process such as selenization or sulfurization).

An apparatus of sputtering a film containing a high vapor pressure material is introduced herein. The apparatus includes a chamber, a sputtering gun installed in the chamber, a complex target disposed on the sputtering gun, and a substrate holder. The complex target includes a main target and a plurality of pellets. A material of the pellets is at least one high vapor pressure material which has a vapor pressure greater than 1×10⁻⁹ torr at 1000° C. The substrate holder is installed in the chamber opposite to the complex target.

A method of sputtering a film containing a high vapor pressure material is further introduced herein. In the method, a sputtering apparatus including above complex target is provided. A sputtering process is performed using the complex target to form a film on a substrate. An annealing process is performed on the film. The complex target includes a main target and a plurality of pellets. A material of the pellets is at last one high vapor pressure material which has a vapor pressure greater than 1×10⁻⁹ torr at 1000° C.

In light of the foregoing, the apparatus and the method introduced herein are capable of controlling the ratio of the high vapor pressure material in the film precisely. Consequently, a film containing a high vapor pressure material and having no impurity phase can be manufactured without performing an additional filling process.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional diagram illustrating an apparatus of sputtering a film containing a high vapor pressure material according to the first exemplary embodiment.

FIGS. 2A and 2B are schematic 3-dimensional (3D) diagrams respectively illustrating different types of complex targets according to the first exemplary embodiment.

FIG. 3A is a schematic cross-sectional diagram illustrating an apparatus of sputtering a film containing a high vapor pressure material according to a second exemplary embodiment.

FIG. 3B is a schematic top view illustrating a metal grid shown in FIG. 3A.

FIG. 4A is a schematic cross-sectional diagram illustrating an apparatus of another variation of the second exemplary embodiment.

FIG. 4B is a schematic 3D diagram illustrating a metal grid shown in FIG. 4A.

FIG. 5 is a composition analysis diagram obtained from an experiment.

### DESCRIPTION OF EMBODIMENTS

Figures in the disclosure are used to describe the exemplary embodiments in details. However, the disclosure can be implemented in various manners and is not limited to the following exemplary embodiments. In fact, these exemplary embodiments are provided to further illustrate the disclosure, so that the scope of the disclosure is understood by persons with common knowledge in the art. In the figures, the sizes and the relative sizes of the layers and the sections are not scaled to make clear.

In the disclosure, the so-called “high vapor pressure material” is a material with a vapor pressure greater than 1×10⁻⁹ torr at 1000° C.

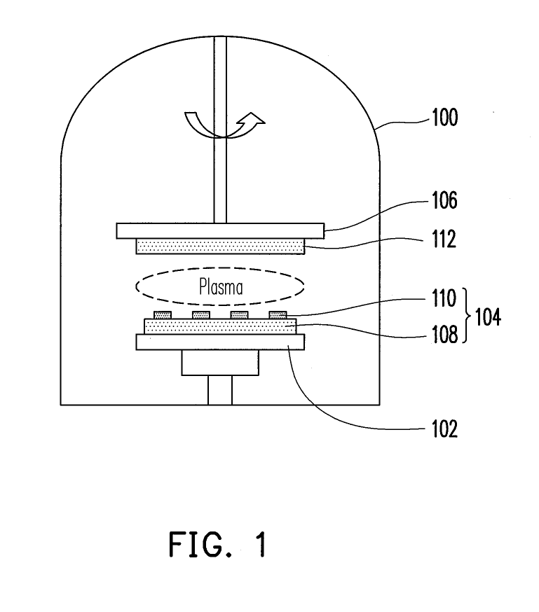

FIG. 1 is a schematic cross-sectional diagram illustrating an apparatus of sputtering a film containing a high vapor pressure material according to a first exemplary embodiment. Referring to FIG. 1, the apparatus of the first exemplary embodiment includes a chamber 100, a sputtering gun 102 installed in the chamber 100, a complex target 104 disposed on the sputtering gun 102, and a substrate holder 106. The complex target 104 includes a main target 108 and a plurality of pellets 110. A material of the pellets 110 is at least one high vapor pressure material, and is selected from a group consisting of magnesium (Mg), zinc (Zn), lithium (Li), tin (Sn), selenium (Se), sulfur (S), aluminum (Al), and a combination thereof, for example. A material of the main target 108 is based on a desired composition of a film. For example, when the composition of the film is copper indium gallium diselenide (CIGS), the material of the main target 108 is CIGS or copper indium gallium (CIG). The substrate holder 106 is installed in the chamber 100 opposite to the complex target 104.

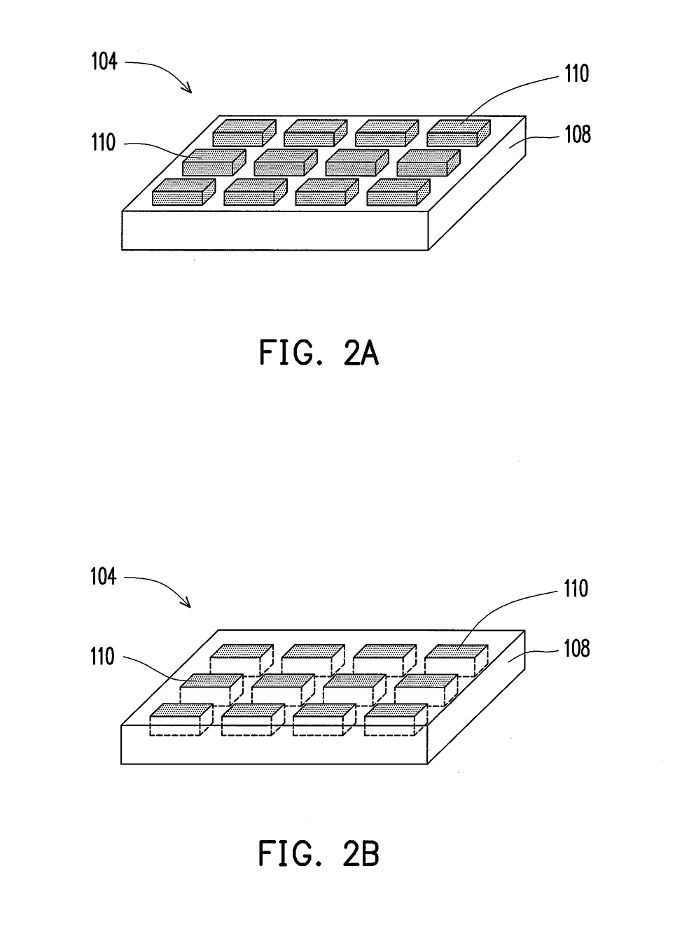

In the first exemplary embodiment, the pellets 110 in the complex target 104 are adhered to the main target 108, as shown in a three-dimensional (3D) diagram of FIG. 2A. Furthermore, the pellets 110 in the complex target 104 can also be embedded in the main target 108, as shown in a 3D diagram of FIG. 2B. The number of the pellets 110 is dependent on the composition of the film required. The shape of the pellets 110 or the main target 108 is defined according to a substrate 112 on the substrate holder 106. For example, when the substrate 112 is a silicon wafer, the main target 108 is circular. However, the disclosure is not limited thereto.

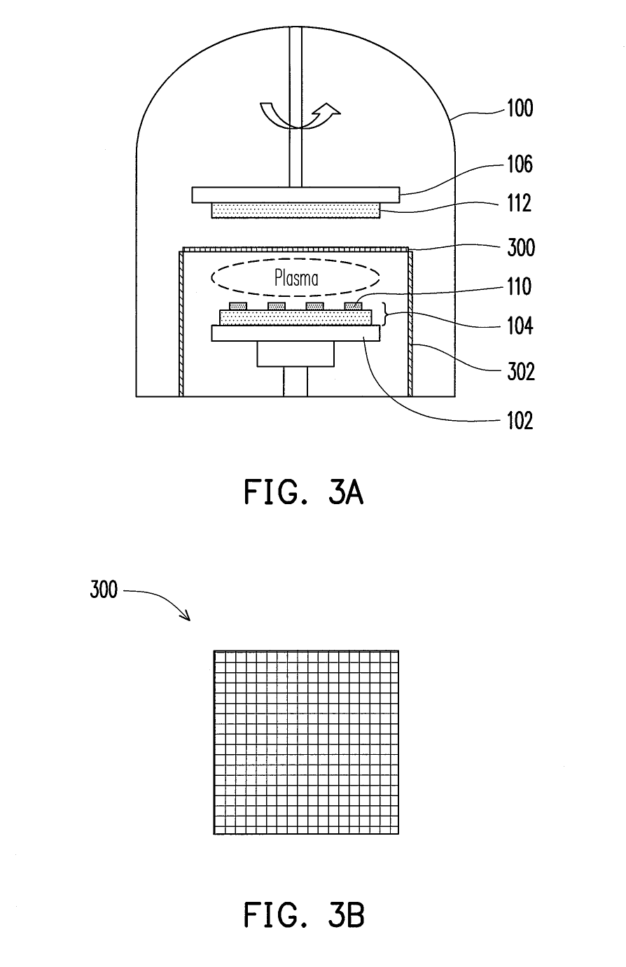

FIG. 3A is a schematic cross-sectional diagram illustrating an apparatus of sputtering a film containing a high vapor pressure material according to a second exemplary embodiment. Here, the same notations in the first exemplary embodiment are used to resemble the same or similar components.

Referring to FIG. 3A, the second exemplary embodiment and the first exemplary embodiment are different in that the second exemplary embodiment has a metal grid 300 disposed between the substrate holder 106 and the complex target 104. As the metal grid 300 prevents charged particles from colliding the substrate 112 directly, defects of the film caused by the collisions of the charged particles to the substrate 112 are reduced, thereby enhancing an electrical property of the film. In this condition, an inductive potential is lowered and a consumption of the pellets 110 in the complex target 104 is consequently decreased.

In the second exemplary embodiment, the metal grid 300 is stacked on the sputtering gun 102 directly or installed in the chamber 100 using a support 302 additionally as shown in FIG. 3A. The metal grid 300 is a planar structure and a schematic top view thereof is shown in FIG. 3B.

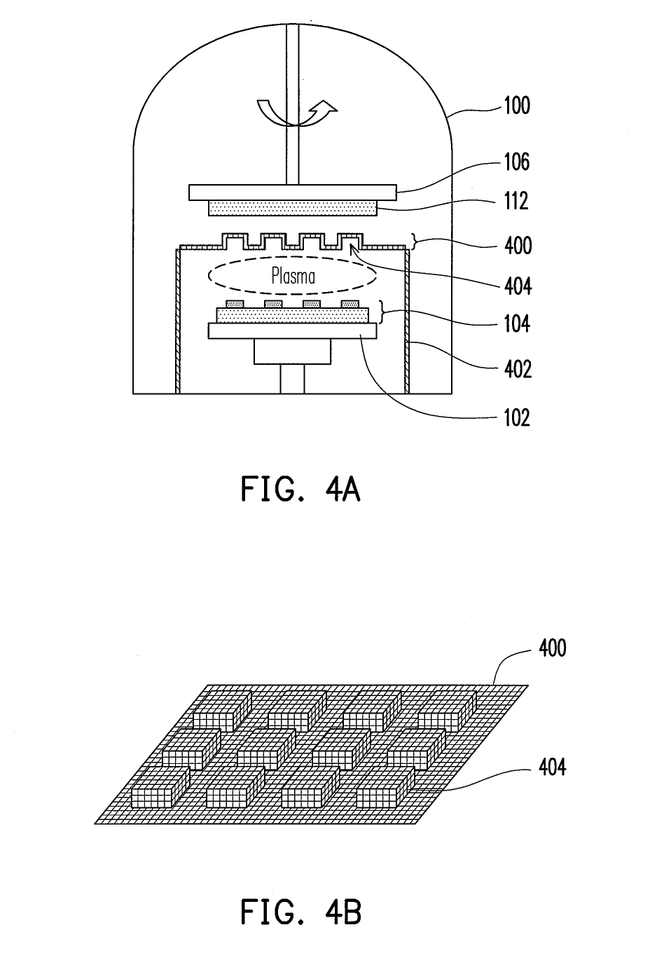

In addition, the metal grid in the second exemplary embodiment has variations. As illustrated in FIG. 4A, a metal grid 400 installed in the chamber 100 with a support 402 is a structure having a plurality of protrusions 404, and a 3D diagram thereof is shown in FIG. 4B. Herein, each of the protrusions 404 in the metal grid 400 protrudes toward the substrate holder 106 corresponding to the location of each of the pellets 110 in the complex target 104, for instance. As a result, a sputtering rate is uniformed.

According to the apparatuses in the first and the second exemplary embodiments, a sputtering method is further introduced in the disclosure. In the method, a sputtering process is performed by utilizing the apparatuses aforementioned to form a film on the substrate (112 shown as in FIG. 1, 3A, or 4A). An annealing process is then performed on the film.

After the foregoing processes, a film containing a high vapor pressure material having a precise ratio is obtained. An experiment is illustrated below to test the effect of the disclosure.

### Experiment

It is desired to form a copper gallium diselenide (CGS) film adopted in a CGS solar cell. An apparatus as that shown in FIG. 1 is provided. A sputtering process is performed using different targets. An annealing process is then performed on the film at 450° C. after sputtering. The targets used in the experiment include (1) a CuGaSe₂ target with a diameter of 3 inches (″), (2) a complex target constituted by a CuGaSe₂ main target with a diameter of 3″ and a Se pellet with a diameter of 1 centimeter (cm), and (3) a complex target constituted by a CuGaSe₂ main target with a diameter of 3″ and three Se pellets with a diameter of 1 cm.

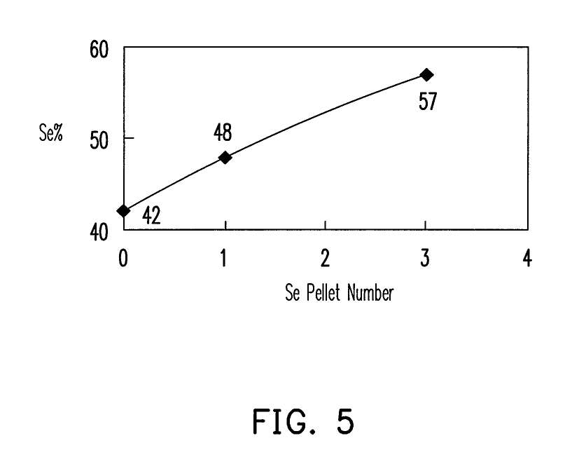

A composition of the film obtained after the annealing is analyzed with an energy dispersive spectrometer (EDS) as shown in FIG. 5. In FIG. 5, a content of Se increases as the number of the pellets increases. Thus, the ratio of the high vapor pressure material in the film can be precisely controlled easily by adjusting the number of the pellets.

The CGS solar cell is adopted as an example in the aforementioned experiment, so the disclosure is generally suitable for the manufacture of solar cells. For instance, the film having the high vapor pressure material can be CIGS, copper indium diselenide (CIS), CGS, copper indium aluminum diselenide (CIAS), copper indium gallium sulphur selenide (CIGSS), copper zinc tin tetrasulfide (CuZnSnS₄), and so on. The apparatus and the method of the disclosure can be further applied in a manufacture of quantum dot solar cells. For example, the material of the pellets in the complex target is replaced with a quantum dot material.

Moreover, when the disclosure is applied in the semiconductor copper process, the material containing the high vapor pressure is aluminum or tin for improving the adherence of a copper wire and reducing an electromigration rate.

In summary, the apparatus and the method of the disclosure are capable of controlling the ratio of the high vapor pressure material in the film precisely without performing additional filling processes (such as selenization or sulfurization). Also, the film does not include any impurity phase. Hence, the disclosure is capable of manufacturing the film containing the high vapor pressure material with the most direct and economical method.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An apparatus of sputtering a film containing a high vapor pressure material, the apparatus at least comprising:
a chamber;
a sputtering gun, installed in the chamber;
a complex target, disposed on the sputtering gun, wherein the complex target comprises a main target and a plurality of pellets, and a material of the pellets is at least one high vapor pressure material with a vapor pressure greater than 1×10⁻⁹ ton at 1000° C.; and
a substrate holder, installed in the chamber opposite to the complex target.

2. The apparatus of sputtering the film containing the high vapor pressure material as claimed in claim 1, wherein the high vapor pressure material is selected from a group consisting of magnesium, zinc, lithium, tin, selenium, sulfur, aluminum, and a combination thereof.

3. The apparatus of sputtering the film containing the high vapor pressure material as claimed in claim 1, wherein the pellets in the complex target are adhered to the main target.

4. The apparatus of sputtering the film containing the high vapor pressure material as claimed in claim 1, wherein the pellets in the complex target are embedded in the main target.

5. The apparatus of sputtering the film containing the high vapor pressure material as claimed in claim 1, further comprising a metal grid disposed between the substrate holder and the complex target.

6. The apparatus of sputtering the film containing the high vapor pressure material as claimed in claim 5, wherein the metal grid is a planar structure or a structure having a plurality of protrusions.

7. The apparatus of sputtering the film containing the high vapor pressure material as claimed in claim 6, wherein each of the protrusions protrudes toward the substrate holder corresponding to a location of each of the pellets.

8. A method of sputtering a film containing a high vapor pressure material, the method comprising:
providing a sputtering apparatus having a complex target comprising a main target and a plurality of pellets, wherein a material of the pellets is at least one high vapor pressure material with a vapor pressure greater than 1×10⁻⁹ ton at 1000° C.;
performing a sputtering process using the complex target to form a film on a substrate; and
performing an annealing process on the film.

9. The method of sputtering the film containing the high vapor pressure material as claimed in claim 8, wherein the high vapor pressure material is selected from a group consisting of magnesium, zinc, lithium, tin, selenium, sulfur, aluminum, and a combination thereof.

10. The method of sputtering the film containing the high vapor pressure material as claimed in claim 8, wherein the pellets in the complex target are adhered to the main target.

11. The method of sputtering the film containing the high vapor pressure material as claimed in claim 8, wherein the pellets in the complex target are embedded in the main target.

12. The method of sputtering the film containing the high vapor pressure material as claimed in claim 8, wherein the method further comprises disposing a metal grid between the complex target and a substrate holder before performing the sputtering process using the complex target.

13. The method of sputtering the film containing the high vapor pressure material as claimed in claim 12, wherein the metal grid is a planar structure or a structure having a plurality of protrusions.

14. The method of sputtering the film containing the high vapor pressure material as claimed in claim 13, wherein each of the protrusions protrudes toward the substrate holder corresponding to a location of each of the pellets.
